(19) United States
(12) Patent Application Publication
(10) Pub. No.: US 2010/0299832 A1
(43) Pub. Date: Dec. 2, 2010

(54) Chiropractic sleeping bag with self contained inflatable air bladders

(76) Inventor: John T. Alford, Spokane, WA (US)

Correspondence Address: THE INVENTORS NETWORK, INC., 332 ACADEMY STREET, CARNEGIE, PA, 15106, US

(21) Appl. No.: 12/454,864

(22) Filed: May 27, 2009

(51) Int. Cl. A47G 9/08; A47C 21/04; A47C 27/08; H01L 31/042

(52) U.S. Cl. 5/413 AM; 5/421; 136/244

(57) ABSTRACT

A combination sleeping bag and air mattress with air bladders includes a sleeping bag having an upper layer openable and closable to a lower layer with a removable liner capable of disposition therebetween for providing additional warmth to the sleeping individual. The lower layer is embedded with a resilient cushioning member for support, and disposed adjacent the resilient cushioning member and throughout the lower layer are interconnected air bladders that when inflated contour to and conform about the individual's body for supporting muscular-skeletal areas such as the head, neck, shoulders and upper and lower lumber regions of the back. The air bladders are inflatable by a bellows and check valve arrangement located at the lower end of the sleeping bag, and the combination sleeping and air mattress includes internally extending heating conductors, a thermal control adjacent the upper end of the sleeping bag, a built-in solar powered radio AM-FM self-contained with controls and clock, and a transponder.

### FIELD OF THE INVENTION

The present invention pertains to sleeping bags, and more particularly pertains to a combination sleeping bag and air mattress that includes inflatable air bladders that contour about the body of the individual for providing skeleto-musculature support and comfort.

### BACKGROUND OF THE INVENTION

Sleeping bags are a necessity for any outdoor activity that requires or necessitates an overnight stay. Such outdoor activities can include Boy Scout and Girl Scout outings, backpacking, hiking, bicycling, and camping (both summer and winter). Although the basic design of the sleeping bag hasn't changed in generations, their water repellant and insulative capabilities have greatly improved through the use of reinforced polyester fabrics and material with one highly effective material known by the trade name GORE TEX. These are materials also from the type of bed known by the trade name of Tempu-Pedic Bed.

However, sleeping on the hard ground is only for the hardy few, and so an air mattress is required for interposition between the ground and the sleeping bag. Air mattresses are bulky and require inflation preferably by a foot pump or an electric air compressor. Thus, many campers are required to pack not only the sleeping bags but also bulky air mattresses and the inflation equipment into the vehicles, trailers, pop-ups, etc. Since camping is a family activity and many families have several children plus guests it may be necessary to pack two or three space-consuming air mattresses.

Moreover, with the increased societal emphasis on providing opportunities for elderly individuals and disabled people of all ages, outdoor recreational activities such as camping have become a prime outlet. Yet such people often need a lightweight and targeted support for their head, neck, shoulders and back that the standard rectangular-shaped bulky air mattress can't provide and wherein certain body regions or areas need more support—or less support as the case may be—than other body areas and regions. And it goes without saying that the more compact, condensed and easily transportable the camping equipment is, the easier it is to involve elderly and disabled individuals in the many outdoor recreational activities where camping at night on the ground and beneath the stars is a major part of the activity.

Thus, the prior art discloses a number of sleeping bags that include various types of covers and mattresses to enhance the convenience and comfort for the user of the sleeping bag.

For example, the Gaiser patent (U.S. Pat. No. 3,798,686) discloses a self-inflatable air mattress and sleeping bag that includes a core of flexible and resilient cellular material and an airtight jacket for enclosing the core.

The Gaiser patent (U.S. Pat. No. 3,877,092) discloses a self inflatable air mattress and sleeping bag that includes a flexible core enclosed by an airtight jacket and a mandrel at one end that facilitates the rolling up of the sleeping bag and flexible straps that fix the mandrel in place when the sleeping bag is rolled up.

The Malcolm patent (U.S. Pat. No. 4,091,482) discloses an inflatable sleeping bag that includes layers of inflatable permeable material and insulating material in the form of a shredded matallized plastic web.

The Adams, III, patent (U.S. Pat. No. 4,862,533) discloses a sleeping bag that includes an air mattress slidably disposed within a zipper controlled pocket of the sleeping bag, and an electric pump or bellows member for inflating the air mattress.

The Tsai patent (U.S. Pat. No. 4,996,733) discloses a sleeping bag and reinforced air mattress that includes inflatable upper and bottom mattresses, a detachable head rest piece and a head covering.

The Lee et al. patent (U.S. Pat. No. 5,528,779) discloses an air-cushioned sleeping bag that includes a bottom portion and a rectangular cover member, an inflatable pillow attached to the bottom portion and a shading member longitudinally attached to the pillow for use as a canopy above the head of the recumbent individual.

The Thomas patent (U.S. Pat. No. 5,553,339) discloses an adjustable air mattress sleeping bag that includes a plurality of elongated flexible air tubes that can be pressurized to support the sleeping bag at the desired height and firmness.

The Gulino patent (U.S. Pat. No. 6,321,400 B1) discloses an air mattress sleeping bag that includes first and second sleeping bag portions and first and second air mattress portions and a self contained air inflation device.

The Lamke patent (U.S. Pat. No. 6,675,414 B2) discloses a sleeping bag with replaceable air mattress that includes an inflatable air mattress having an inflatable portion and a peripheral extension.

Nonetheless, despite the ingenuity of the above devices, there remains a need for a chiropractic sleeping bag that includes inflatable air bladders that contour and conform to the individual's body for supporting select areas of the individual's body while the individual is disposed within the sleeping bag.

### SUMMARY OF THE INVENTION

The present invention comprehends a combination chiropractic sleeping bag and air mattress with selectively inflatable air bladders for providing chiropractic musculo-skeletal support of crucial areas of the body, such as the head, neck, upper lumbar region and lower lumbar region. The combination sleeping bag and air mattress of the present invention allows individuals with back problems, and even disabled individuals, to obtain a restful and comfortable night's sleep on any surface, and thereby liberates them from the limitations of only sleeping in a motel or recreational vehicle.

The combination chiropractic sleeping bag and air mattress with air bladders includes a sleeping bag includes a waterproof shell further defined by an upper layer integrally joined to a lower layer along one long edge. The opposite long edge includes a sleeping bag opening and closure in the form of a zipper. The upper and lower layers are waterproof, and the upper covering layer includes an interior cavity that includes a conventional fiberfill for insulation. The sleeping bag includes nylon straps that can be tied together when the sleeping bag is rolled up, and a carrying strap for transporting the sleeping bag. Moreover, the sleeping bag can include a liner for additional warmth with the liner capable of removal insertion within the upper layer or between the upper and lower layers of the sleeping bag.

The lower layer includes an interior cavity, and arranged and filling the interior cavity is a resilient cushioning member preferably of a conventional memory foam material. Inflatable air bladders are also encased within the cavity of the lower layer in addition to the resilient cushioning member. The inflatable air bladders can take on various arrangements with the resilient cushioning member being disposed around and between the air bladders and conform to and contour about the various areas of the individual's body. In one embodiment there are at least four interconnected inflatable air bladders, specifically a head bladder, a major body portion bladder further divided into an upper lumbar support bladder and a lower lumbar support bladder, and a pair of side bladders. The air bladders are arranged to provide maximum support for crucial musculo-skeletal areas and regions such as the head, neck, shoulders, back (both upper back area and lower back area), and hips, especially for individuals with joint and back pain, arthritic conditions, and even for disabled people, all of whom may want to go camping and enjoy the outdoors but require the additional and targeted support that the air bladders of the present invention provide. In addition, the air bladders provide maximum support for the various pressure points of the body by providing even support for contouring to the individual's body. The air bladders are interconnected by air channels or lines, and the bladders can be inflated and deflated by conventional means, a preferred one being a foot pump or bellows hidden within and enclosed at the lower foot end of the sleeping bag with air intake and egress controlled by a check valve connected to the bellows, and the bellows being in direct air flow communication with the major body portion bladder. Furthermore, for a more selective and targeted inflation of the bladders, a secondary inlet can be included with a preferable location being at the upper end of one of the side bladders, and selected bladders, such as the side bladders and the central major body portion bladder, can include baffles extending through the mid-portion of the aforesaid bladders. Thus, the inflation of the air bladders can be further controlled and regulated by regulating the amount of air delivered through the check valve and bellows at the lower foot end of the sleeping bag and/or the amount of air delivered to the upper portions of the air bladders through the secondary inlet. Various types of manual and electric air compressors can be attached to the secondary air inlet for discharging air into the air bladders.

Additional features for the combination chiropractic sleeping bag and air mattress can include heating conductors extending through the upper layer similar to the heating conductors enclosed within a heating blanket with a thermal control located adjacent the upper end of the sleeping bag and the head bladder, and also extending throughout the lower layer of the sleeping bag. Also, the sleeping bag can include a built-in radio electrically interconnected to solar panels both of which are preferably located at the upper end of the sleeping bag to minimize the extension of electrical wires through the sleeping bag. Furthermore, the sleeping bag can include solar panels for heating with the required solar batteries being stored in the lower foot end. It should also be noted that hand generators can be utilized that supplement the solar panels; the hand generator to assist in charging batteries for maintaining the heating and keeping the radio and transponder operational during periods of little or no sun. It is also contemplated that the hand generator would be very useful in the Arctic region during the six months of the year when the sun doesn't shine.

It is an objective of the present invention to provide a sleeping bag and mattress with self-contained inflatable air bladders that conform to and contour about the body of the individual when the air bladders are inflated.

It is another objective of the present invention to provide a sleeping bag and mattress with self contained inflatable air bladders that insulates the individual from the cold when used outdoors and which can be easily and quickly inflated and deflated.

It is yet another objective of the present invention to provide a sleeping bag and mattress with self contained inflatable air bladders that is composed of high quality anti-mold, anti-dry rot, and anti-moisture components.

It is still yet another objective of the present invention to provide a sleeping bag and mattress with self-contained inflatable air bladders wherein heating conductors can be extended throughout the sleeping bag for heating the sleeping bag.

It is still yet a further objective of the present invention to provide a sleeping bag and mattress with self-contained inflatable air bladders that includes an easy-to-install and easy-to-remove comfort liner that can be disposed within the sleeping bag for providing warmth to the individual recumbent therein.

Another objective of the present invention is to provide a sleeping bag and mattress with self-contained inflatable air bladders that includes memory foam as the cushioning and supporting layer for the individual recumbent and sleeping within the sleeping bag.

Yet another objective of the present invention is to provide a sleeping bag and mattress with self-contained inflatable air bladders that is easy to pack, carry and transport.

Still yet another objective of the present invention is to provide a sleeping bag and mattress with self contained inflatable air bladders wherein the air bladders are arranged within the sleeping bag to provide comfort and support for specific areas of the individual's body such as the head, neck, shoulders, upper back and lower back.

Yet still another objective of the present invention is to provide a sleeping bag and mattress with self contained inflatable air bladders that is constructed from durable, lightweight materials, is stain resistant and is easy to clean.

Yet still a further objective of the present invention is to provide a sleeping bag and mattress with self-contained air bladders wherein the air bladders can be selectively inflated to meet the comfort and support levels desired by each individual.

A further objective of the present invention is to provide a sleeping bag and mattress with self-contained air bladders that has application in military field and special operations environments.

A still further objective of the present invention is to provide a sleeping bag and mattress with self-contained air bladders for stabilizing patients for air and ground transport and for use in emergency applications.

Another still further objective of the present invention is to provide a sleeping bag and mattress with self-contained air bladders that has specific emergency applications such as with hospitals, with field hospitals, for search and rescue missions and operations, medical emergency flights for the stabilization of patients due to injuries, and for thermal applications such as the treatment of a frozen lake survivor.

A still yet further objective of the present invention is to provide a sleeping bag and mattress with self-contained air bladders that has more specific military applications for branch of the service such as the Army and the Marines and also for such units as S.O.G, S.F., and S.T.

These and other objects, features, and advantages will become apparent to those skilled in the art upon a perusal of the following detailed description read in conjunction with the accompanying drawing figures and appended claims.

### BRIEF DESCRIPTION OF THE DRAWINGS

FIG. 1 is a perspective view of the sleeping bag and mattress with self-contained inflatable air bladders of the present invention illustrating the location of the hidden foot pump and the check valve through which air is delivered to the bladders and the disposition of an individual within the sleeping bag;

FIG. 2 is a perspective view of the sleeping bag and mattress with self-contained inflatable air bladders of the present invention illustrating the use of various mechanical devices to provide air into the bladders at the upper end of the of the sleeping bag;

FIG. 3 is a sectioned elevational view of the sleeping bag and mattress with self-contained inflatable air bladders of the present invention taken along lines 3-3 of FIG. 1 illustrating the disposition of the resilient cushioning member and the bladders for the head, feet and upper and lower lumbar support inflated for use;

FIG. 4 is a sectioned elevational view of the sleeping bag and mattress with self-contained air bladders of the present invention taken along lines 3-3 of FIG. 1 illustrating the disposition of the resilient cushioning member and the bladders for the head, feet and upper and lower lumbar areas with the bladders deflated when the sleeping bag is not being used;

FIG. 5 is an enlarged sectioned view of the sleeping bag and mattress with self-contained air bladders of the present invention illustrating a storage compartment for the sleeping bag;

FIG. 6 is a partial perspective view of the sleeping bag and mattress with self-contained air bladders of the present invention illustrating the use of an air compressor to inflate the air bladders;

FIG. 7 is a schematic view of the sleeping bag and mattress with self-contained air bladders of the present invention illustrating the disposition of the air bladders and their air flow interconnection to each other;

FIG. 8 is a perspective view of the sleeping bag and mattress with self-contained air bladders of the present invention illustrating the disposition of the liner and the nylon tie straps and the carrying strap;

FIG. 9 is a schematic view of the sleeping bag and mattress with self-contained air bladders of the present invention illustrating the disposition of the air bladders and the use of baffles to provide a more selective inflation of the air bladders;

FIG. 10 is a perspective view of the sleeping bag and mattress with self-contained air bladders of the present invention illustrating the heating conductors extending through the upper layer and the lower layer of the sleeping bag, a thermal control, and a solar powered built-in radio located at the upper end of the sleeping bag; and

FIG. 11 is a schematic view of the sleeping bag and mattress with self-contained air bladders of the present invention illustrating the contouring and conformance of the air bladders about and beneath the individual after the bladders have been inflated to the desired level.

### DETAILED DESCRIPTION OF THE PREFERRED EMBODIMENT

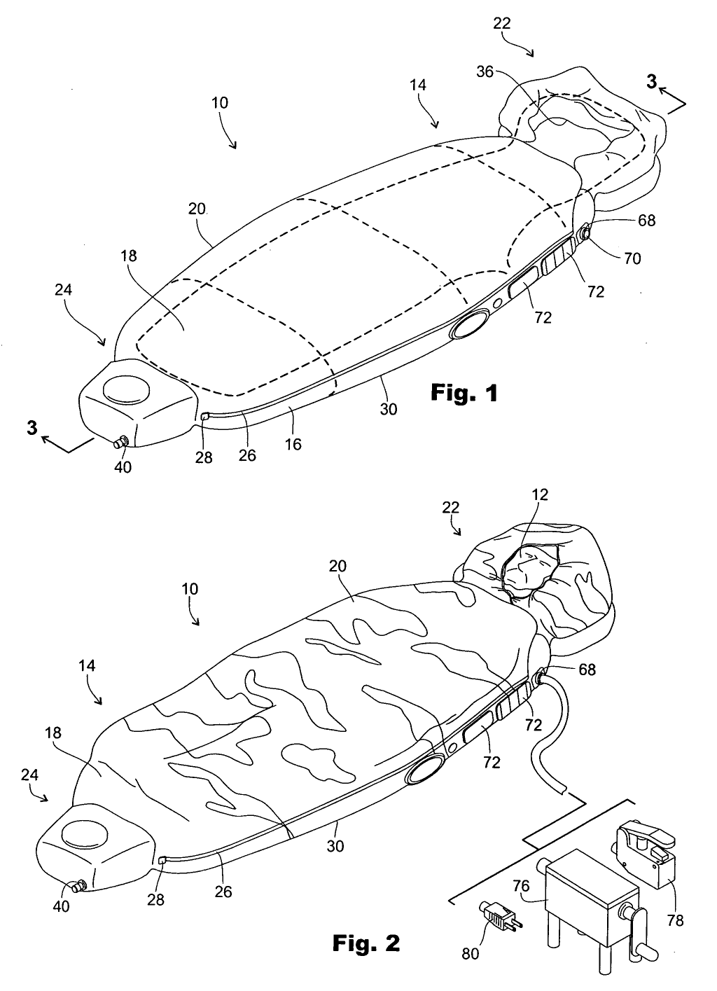

Illustrated in FIGS. 1-11 is a portable chiropractic sleeping bag and mattress with self-contained inflatable air bladders 10 for providing warmth, comfort and support for an individual 12 enclosed and recumbent within the sleeping bag 10. The all-in-one sleeping bag and mattress 10 is easy to inflate and deflate—without the use of tools—and provides a warm and restful night's sleep thereby freeing the individual from being limited to sleeping in only a motel or recreational vehicle. The sleeping bag 10 of the present invention provides the individual 12 with a comfortable and restful night's sleep by contouring to and conforming about specific areas and regions of the body, such as the head, neck, shoulders, and upper lumbar region and lower lumbar region of the back, upon inflation of various air bladders. The sleeping bag 10 is especially useful for individuals with chiropractic problems that need enhanced support and cushioning for the critical aforedescribed body areas and regions in order to alleviate the stress and strain resulting from sleeping on a hard, uncomfortable surface. In addition, the sleeping bag 10 has military applications in the field and for use with special operations in inclement seasons throughout the world allowing units to operate longer due to weather conditions and soldier rest. Also, the sleeping bag 10 has application in and for emergency rescue situations by allowing the patient to be better supported (stabilized) in circumstances that include ground rescue, car accidents, train derailments, plane crashes and air flight.

Thus, illustrated in FIGS. 1-11 is an all-in-one chiropractic sleeping bag and mattress 10 that includes a waterproof outer shell 14 within which the recumbent individual 12 is disposed for resting or sleeping. The outer shell 14 includes a lower layer 16 and an upper layer 18 integrally adjoined to each other along one long side 20, and the outer shell 14 further includes an upper head end 22 and an opposite lower foot end 24. The upper layer 18 opens and closes to the lower layer 16 by a zipper 26 and zipper catch 28 extending along the opposed sleeping bag access side 30 with the zipper 26 extending therealong from the lower end 24 to the upper end 22. The access side 30 of the outer shell 14 is the side through which the individual 12 enters and exits the sleeping bag 10. The zipper catch 28 can be extra-large for easy access and to enhance leverage for easily opening and closing the sleeping bag 10. As shown in FIGS. 8 and 10, at least one pair of nylon tie straps 32 extend from outer shell 14 of the sleeping bag 10 for tying up the sleeping bag 10 after the sleeping bag 10 has been rolled up for transport or storage, and a handle strap 34 is attached to the outer shell 14 for easily carrying the rolled-up sleeping bag 10. The upper end 22 includes a face opening 36 through which the face of the individual 12 can project, and the lower end 24 adjacent the lower layer 16 includes a chamber 38 wherein an air delivery means is enclosed. The face opening 36 is integrally formed from the upper layer 18 of the outer shell 14 of the sleeping bag 10. The air delivery means includes a manually operable check valve 40 in air flow communication with the bladders, and indirectly with a foot operable bellows 42. The check valve 40 externally projects from the lower foot end 24 of the sleeping bag 10 so that the valve 40 can be easily manually opened and closed. The check valve 40 is closed to keep the delivery of air into the bladders through the action of the foot bellows 42 within the bladders. For deflation of the bladders the check valve 40 is opened so that air can egress back through the check valve 40 for deflation of the bladders.

As shown in FIG. 8, the sleeping bag 10 includes a liner 44 that in one configuration can be placed between the upper layer 18 and the lower layer 16 for providing additional warmth when the sleeping bag 10 is used, for example, in the fall and winter seasons or in cold climates. The liner 44 is removable for cleaning or when the sleeping bag 10 is used in warm weather conditions.

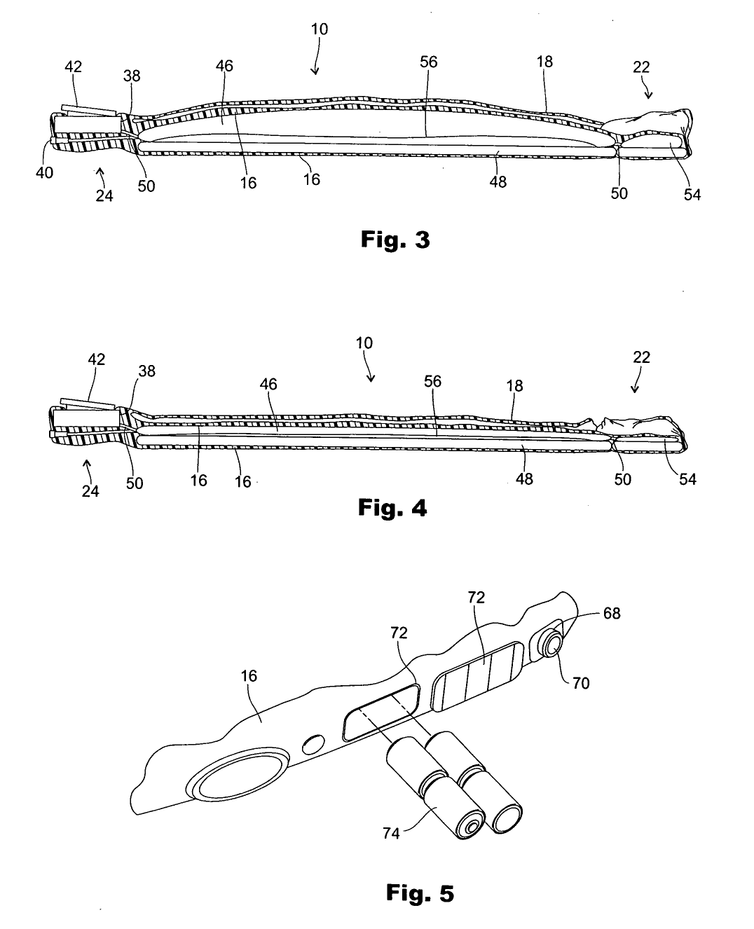

As shown in FIGS. 3, 4, 7 and 9, the sleeping bag 10, and more specifically, the lower layer 16 of the shell 14, includes an interior cavity 46 that extends substantially the length of the lower layer 16. Disposed within the interior cavity 46 are several structural members that provide for the physical cushioning and chiropractic support of the individual 12 that is recumbent within the sleeping bag 10. Enclosed within the interior cavity 46 is a resilient cushioning member 48 that is preferably of a conventional flexible memory foam material. In addition, disposed adjacent and about the resilient cushioning member 48 are inflatable air bladders capable of adjustable inflation for providing chiropractic support to the head, neck, shoulders, and upper lumbar and lower lumbar regions of the back thereby alleviating or eliminating altogether stress and strain on those body regions or areas. Air channels or air lines 50 interconnect the inflatable bladders to each other, and the air bladders are inflatable by the operation of the check valve 40 and foot bellows 42. The inflatable air bladders are preferably manufactured from reinforced, high quality, puncture proof vulcanized rubber with the surfaces of the bladders having applied thereon or treated with anti-moisture, anti-dry rot, and anti-mold agents or compounds. In addition, each bladder is encased in a nylon canvass 52.

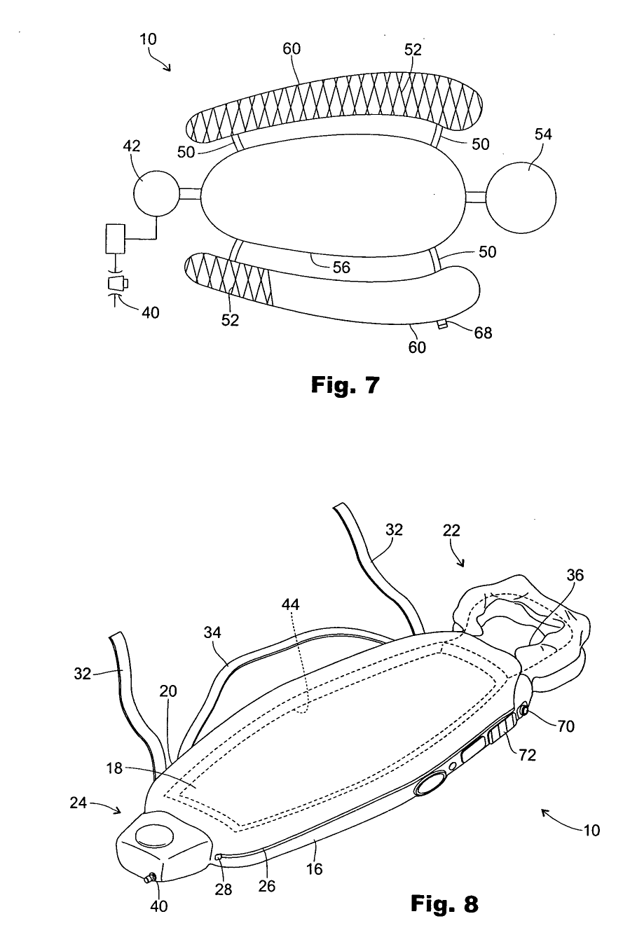

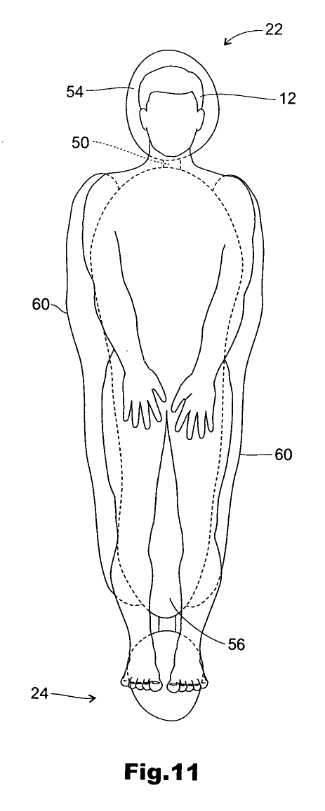

The air bladders can be configured in many different arrangements for supporting the various areas and regions of the individual's body. More significantly, the air bladders can be arranged to provide selected and targeted chiropractic musculo-skeletal relief and comfort to such areas as the head, neck, shoulders, and the upper and lower lumbar regions of the back by both supporting those body areas and, upon inflation of the bladders, contouring about and closely conforming to the individual 12 as he or she reposes within the sleeping bag 10. Thus, shown in FIGS. 7, 9 and 11 is one preferred arrangement of the air bladders that both supports the various body regions or areas and provides for the contouring and conformance of the bladders about the recumbent individual 10. Specifically, the air bladders of FIGS. 7, 9 and 11 include a head bladder 54, a central major body portion bladder 56 for supporting the back and thighs of the individual 12, and a pair of opposed kidney-shaped side bladders 60. The bladders 54-60 are interconnected via the air channels 50, and the distinctive shape of the side bladders 60 allows the side bladders 60 to conform to and contour about the left and right sides of the torso of the individual as well as contouring to and about the legs of the individual 12 when the side bladders 60 are inflated and the individual is recumbent upon the lower layer 14 of the sleeping bag 10. FIG. 11 illustrates the contouring of the bladders 54-60 about the individual's body for providing support to the specific areas or regions such as the head, neck, shoulders, and upper and lower lumbar regions. The disposition of the air bladders 54-60 of the present invention is a marked improvement over, and clearly advantageous to sleeping on a standard flat air mattress that when inflated resembles sleeping on an unyielding slab, and in which certain areas of the body of the recumbent individual 12 may not actually be in contact with or supported by the conventional mattress during the entire period the individual is sleeping on the conventional mattress.

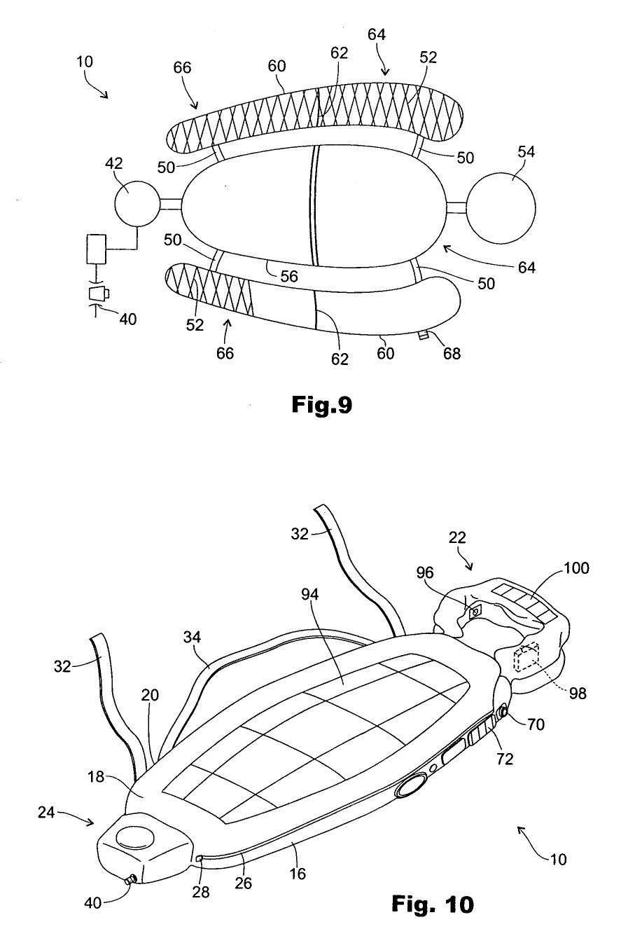

As shown in FIG. 9, the bladders 54-60 can be configured to provide for a more selective and targeted inflation so that specific areas of the body can have more—or less—support than other areas. Specifically, both side bladders 60 and the central bladder 56 can each include a baffle 62 that bisects the respective bladders 56 and 60 and thereby limits or wholly prevents air flow from one half portion or section to the other half portion or section of the respective bladders 56 and 60. The baffles 62 shown in FIG. 9 thus divide the side bladders 60 and the central bladder 56 into an upper portion 64 and a lower portion 66 with the lower portions 66 inflatable through the check valve 40 and foot bellows 42 arrangement shown in FIGS. 1-4 and 6. The upper portion 64 of bladder 56 corresponds to and supports the upper lumbar region of the individual's back, and the lower portion 66 of the bladder 56 corresponds to and supports the lower lumbar region of the individual's back. In order to inflate the upper portions 64 of the bladders 56 and 60 shown in FIG. 9, a secondary air inlet 68 with a removable cap or lid 70 is provided on at least one side bladder 60. The air inlet 68 would specifically direct air into the head bladder 54 as well as the upper portions 64 of the side bladders 60 and the central bladder 56.

For example, should the individual 12 desire more support about the head, neck and shoulders, the head bladder 54 and the upper portions 64 of the central bladder 56 and the side bladders 60 can be inflated to a greater degree than the lower portions 66 of the aforesaid bladders 56 and 60 by discharging more air through the secondary inlet 68 than through the check valve 40 and foot bellows 42. On the other hand, should the individual 12 desire more support for the thighs and legs, then a greater amount of air can be delivered through the check valve 40 and foot bellows 42 to inflate the lower portions 66 of the central bladder 56 and the side bladder 60 while the head bladder 54 and the upper portions 64 of the side bladders 60 and the central bladder 56 would be less inflated. Thus, the bladder arrangement shown in FIG. 9 would be especially advantageous for an individual having neck, back or leg problems and for which the inflation of the various bladders 54-60 can be carefully selected and adjusted to obtain a very specific level or amount of firmness.

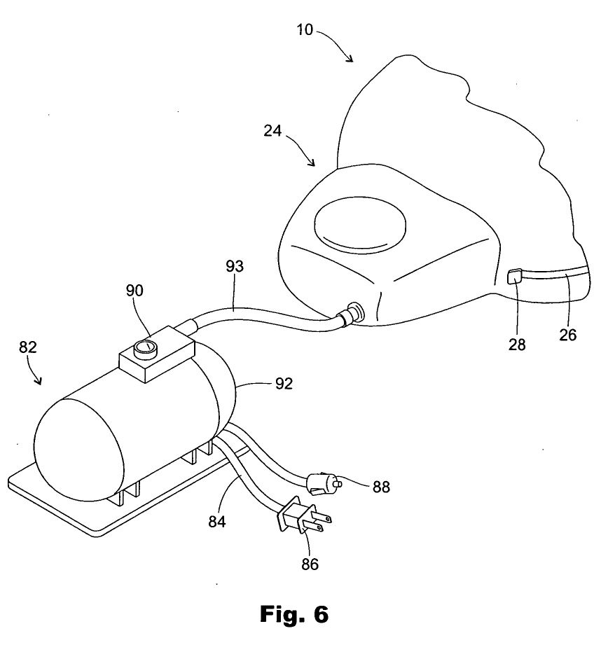

As shown in FIGS. 1, 2 and 5, the sleeping bag 10 can include auxiliary storage compartments 72 preferably located along the zipper side of the lower layer 16 of the sleeping bag 10. The auxiliary storage compartments 72 can be used to store small items such as batteries 74, pocket flashlights, watches, pill bottles, cameras, cell phones, etc. that the individual 12 would want to have in close proximity. In addition, a number of different types of pumps and compressors can be used to deliver air into the bladders 54-60. FIG. 2 illustrates a manual hand-type crank air pump 76 and a lever-operated metered pump 78 as well as an electrical plug 80 for an electric air compressor. A more powerful (greater horsepower) electric compressor 82 is shown in FIG. 6, and includes an electrical cord 84 and plug 86, a toggle switch 88, and an air pressure gauge 90 mounted on the tank 92 of the air compressor 82. A flexible air line 93 extends from the gauge 90 for attachment to the check valve 40 for delivering air into the bladders 54-60. Also, the electric batteries are capable of being charged from the hand generator; the hand generator also powers the batteries and the heating conductors 94 and the radio 98 with the hand generator more for charging than for powering.

FIG. 10 includes several enhancements to the sleeping bag 10 of the present invention. The enhancements include heating conductors 94 extending throughout the sleeping bag 10, and preferably through the lower layer 16 and upper layer 18 of the sleeping bag 10 that are controlled by a thermal control 96 built-in to and located at the upper end 22 of the sleeping bag 10 adjacent the face opening 36 but not interfering with the disposition of the individual's face or head when enclosed by, and partially projecting through, the face opening 36 of the sleeping bag 10. Also, the enhancement can include a small built-in radio 98 located at the upper end 22 of the sleeping bag 10 that is powered by small solar panels 100 externally mounted on the upper layer 18 of the sleeping bag 10, and electrically interconnected to the radio 98. It is assumed radio 98 is a representative standard radio having all the proper controls and is a self-contained AM-FM/radio clock combination and also can include satellite radio functions, features, and capabilities. Also, a transponder can be included with other elements and features such as the radio 98.

Actually deploying the chiropractic sleeping bag and mattress and self-contained bladders 10 of the present invention for use would essentially be the same as using a conventional sleeping bag. After selecting and clearing the appropriate site for the sleeping bag 10 the nylon straps 32 would be untied and then the sleeping bag 10 would be unrolled. The liner 44 would be installed if desired, and then the check valve 40 would be opened so that air could be discharged into the bladders 54-60 by pumping the foot bellows 42 until the bladders 54-60 are inflated to the desired level. The check valve 40 would then be closed and the upper layer 18 would be unzipped from the lower layer 16 (or being inflation of the bladders 54-60) for actually sleeping in the sleeping bag 10. The aforedescribed compressors 76, 78, or 82 could be used if electric is available at the site. The secondary inlet 68 could also be used to discharge air into the bladders 54-60 for obtaining a more selective and targeted inflation of the air bladders 54-60 if the bladders 56 and 60 include baffles 62 as shown in FIG. 9. In order to deflate the bladders 54-60 the check valve 40 would be opened so that rolling up the sleeping bag 10 and forces air out of all the bladders 54-60 and for egress back through the check valve 40. The sleeping bag 10 can then be tied up using the nylon straps 32 ready for its next use.

The foregoing is considered as only illustrative of the principles of the invention, and as numerous modifications, alterations, and variations will readily occur to those skilled in the art, it is not desired to limit the invention to the exact construction and operation as shown and described, but to encompass all suitable modifications and equivalents that may fall within the scope of the invention.

I claim:

1. A combination chiropractic sleeping bag and air mattress, comprising:
an outer water proof shell having a long side for adjoining a lower layer to an upper layer;
the outer shell further defining an upper head end and an opposite lower foot end;
an openable and closable access side opposite of the long side and through which an individual passes between the upper layer and lower layer for sleeping within the sleeping bag;
a face opening integrally formed on the upper layer adjacent the upper head end and through which the face of the individual projects when the individual is sleeping within the sleeping bag;
the lower layer including an interior cavity substantially coextensive with the lower layer;
a resilient cushioning member disposed within the interior cavity of the lower layer for providing support and comfort to the individual when the individual is recumbent upon the lower layer of the sleeping bag;
an inflatable head bladder enclosed within the lower layer at the upper head end thereof for supporting the head of the individual;
an inflatable major central body portion bladder enclosed within the lower layer for supporting the upper lumbar region and the lower lumbar region of the back of the individual;
a pair of inflatable side bladders enclosed within the lower layer with each side bladder located on either side of the major central body portion bladder with the side bladders conforming to and contouring about the torso and legs of the individual;
a foot bellows enclosed by the outer shell and located at the lower foot end thereof and in air flow communication with the head bladder, the central major body portion bladder and the side bladders for inflating the head bladder, the central major body portion bladder and the side bladders;
a check valve interconnected to the head bladder, the central major body portion bladder and the side bladders capable of being closed to maintain air within the bladders after inflation thereof and of being opened for allowing the bladder to deflate; and
whereupon the foot bellows is manually operable for inflating the head bladder, the side bladders, and the major central body portion bladder so that the head bladder, the side bladders, and the major central body portion bladder provide chiropractic comfort and support to the head, neck, shoulders, upper lumbar region and lower lumbar region of the back, and the legs of the individual.

2. The combination chiropractic sleeping bag and air mattress of claim 1 further comprising a secondary air inlet interconnected to and in air flow registration with at least one of the side bladders and through which air can be delivered for inflating the head bladder, the side bladders, and the major central body portion bladder.

3. The combination chiropractic sleeping bag and air mattress of claim 2 further comprising at least one auxiliary storage compartment located adjacent the access side of the outer shell and extending within the lower layer.

4. The combination chiropractic sleeping bag and air mattress of claim 3 further comprising a plurality of heating conductors extending through at least the upper layer of the outer shell for providing warmth to the individual recumbent within the sleeping bag.

5. The combination chiropractic sleeping bag and air mattress of claim 4 further comprising a thermal control located at the upper head end of the outer shell for selectively adjusting the amount of heat produced by the heating conductors.

6. The combination chiropractic sleeping bag and air mattress of claim 5 further comprising a radio located at the upper head end of the outer shell.

7. The combination chiropractic sleeping bag and air mattress of claim 6 further comprising solar panels externally mounted to the outer shell adjacent the upper head end and in electrical interconnection with the radio for providing power to the radio.

8. A combination sleeping bag and air mattress with self-contained bladders for providing chiropractic relief and support for the head, neck, shoulders, upper lumbar region and lower lumbar region of the back, and the legs of an individual recumbent upon the lower layer and within the sleeping bag, comprising:
an outer waterproof shell having a long side for adjoining a lower layer to an upper layer;
the outer shell further including an upper head end and an opposite lower foot end;
an access side opposite of the long side that is selectively opened and closed for providing the individual with access to the sleeping bag;
a face opening integrally formed on the upper layer adjacent the upper head end and through which the face of the individual projects when the individual is recumbent on the lower layer;
the lower layer including an interior cavity that is substantially coextensive with the lower layer;
a resilient cushioning member disposed within the interior cavity of the lower layer for providing support to the individual when the individual is recumbent on the lower layer;
an inflatable head bladder that is enclosed within the lower layer adjacent the upper head end of the outer shell;
an inflatable major central body portion bladder that is enclosed within the lower layer for supporting the upper lumbar regions and lower lumbar region of the back of the individual;
a pair of inflatable side bladders enclosed within the lower layer with the side bladders located on both sides of the major central body portion bladder;
air delivery means interconnected to the head bladder, the major central body portion bladder and the side bladders for inflating the head bladder, the major central body portion bladder and the side bladders;
a check valve interconnected to the head bladder, the major central body portion bladder and the side bladders and which is closed for maintaining the air within the bladders and opened for allowing the deflation of the bladders; and
whereupon inflation of the head bladder, the major central body portion bladder and the side bladders causes the head bladder, the major central body portion bladder and the side bladder to conform to and contour about the body of the individual thereby providing chiropractic support and comfort to the head, neck, shoulders, upper lumbar region and lower lumbar region of the back, and the legs of the individual when the individual is recumbent on the lower layer and enclosed within the sleeping bag.

9. The combination sleeping bag and air mattress with self-contained bladders of claim 8 wherein the air delivery means includes a foot bellows enclosed by the outer shell and located at the lower foot end and which is in air flow registration with the head bladder, the major central body portion bladder and the side bladders for inflating the head bladder, the major central body portion bladder and the side bladders.

10. The combination sleeping bag and air mattress with self-contained bladders of claim 9 further comprising a secondary air inlet interconnected to and in air flow registration with at least one of the side bladders and through which air can be delivered for inflating the head bladder, the side bladders, and the major central body portion bladder.

11. The combination sleeping bag and air mattress with self-contained bladders of claim 10 further comprising at least one auxiliary storage compartment located adjacent the access side of the outer shell and extending into the lower layer.

12. The combination sleeping bag and air mattress with self-contained bladders of claim 11 further comprising a plurality of heating conductors extending through the outer shell for providing warmth to the individual enclosed within the sleeping bag.

13. The combination sleeping bag and air mattress with self-contained bladders of claim 12 further comprising a thermal control located at the upper head end of the outer shell and electrically interconnected to the heating conductors for selectively adjusting the amount of heat produced by the heating conductors.

14. The combination sleeping bag and air mattress with self-contained bladders of claim 13 further comprising a radio located at the upper head end and integrally built in to the outer shell of the sleeping bag.

15. The combination sleeping bag and air mattress with self-contained bladders of claim 14 further comprising solar panels externally mounted to the outer shell and electrically interconnected to the radio for providing power to the radio.
